(19) United States
(12) Patent Application Publication
(10) Pub. No.: US 2020/0303687 A1
(43) Pub. Date: Sep. 24, 2020

(54) MANUFACTURING METHOD OF OLED DISPLAY PANEL

(71) Applicant: SHENZHEN CHINA STAR OPTOELECTRONICS SEMICONDUCTOR DISPLAY TECHNOLOGY CO. LTD., Shenzhen, Guangdong (CN)

(72) Inventor: Hualong LIU, Shenzhen Guangdong (CN)

(21) Appl. No.: 16/339,384

(22) PCT Filed: Mar. 21, 2019
(86) PCT No.: PCT/CN2019/078976

§ 371 Date: Apr. 4, 2019

(30) Foreign Application Priority Data
Jan. 22, 2019 (CN) 201910060079.X

(51) Int. Cl. H01L 51/56; H01L 51/00; H01L 51/52

(52) U.S. Cl. CPC H01L 51/56; H01L 51/0017; H01L 2251/308; H01L 51/5253; H01L 2251/306; H01L 51/003

(57) ABSTRACT

A manufacturing method of an organic light emitting diode (OLED) display panel, includes: supplying a base substrate, forming an anode layer on the base substrate, covering a protective layer on the protective layer, forming a pixel defining layer on the protective layer and the base substrate, enclosing the pixel defining layer as a pixel aperture on the protective layer, and etching the protective layer in the pixel aperture to expose the anode layer.

### BACKGROUND

### 1. Field of the Disclosure

The present disclosure relates to the field of display panel, and more particularly, to a manufacturing method of an organic light emitting diode (OLED) display panel.

### 2. Description of the Related Art

Statements here only provide background information related to the present disclosure, without necessarily constituting the related art.

The main method for manufacturing an organic light emitting diode (OLED) device deposition and printing. Nowadays, the use of full-evaporation process for the manufacturing of an OLED display in large and small sizes with respect to the printing technology is quite mature so the OLED display has been commercially manufactured. However, material utilization is low using the full-evaporation technology so to manufacture a device with a high resolution is a difficult task. The material utilization is up to 90% using the printing technology for manufacturing the OLED device. On the other hand, the cost of manufacturing the OLED device using the printing technology is about 17% lower compared with the whole deposition technology. Besides, no masks are necessary in the printing process. Therefore, the high-resolution OLED display can be manufactured using the printing process.

The printing process includes indium tin oxides (ITO) anode layer patterned to form a pixel defining layer to form a pixel aperture. The edge of the ITO coincides with the pixel defining layer. During the process of printing, the organic functional ink material fails to be spread out the surface of the ITO anode layer completely, and micron-sized foreign particles exist in some of the pixels. Furthermore, the organic functional layer 7 formed after drying is equipped with the edge, and the anode layer 3 where the residue of the pixel defining layer or the foreign particles appear is not covered with the organic functional layer. Accordingly, the OLED display panel not only emits light unequally but also shows mura like bright or dark spots, which seriously affects the display effect and service life of the OLED display panel.

In summary, some problems occur when the organic functional layer is printed on the anode layer of the light emitting area in the manufacturing process of the OLED display panel. The problems are that the organic functional ink material fails to be spread completely, and thereby, the display effect of the OLED display panel is very poor and the service life is short.

### SUMMARY

The present disclosure proposes a manufacturing method of an organic light emitting diode (OLED) display panel. A protective layer covers an anode layer. Then, a pixel defining layer and a pixel aperture are formed. Finally, the protective layer on the anode layer is removed. The technical problem of the related art that the display effect and the service life of an OLED display panel are not influenced by unsuccessful spreading of ink materials when an organic functional film is printed on the anode layer.

According to one embodiment of the present disclosure, a manufacturing method of an organic light emitting diode (OLED) display panel includes: supplying a base substrate, forming an anode layer on the base substrate, covering a protective layer on the protective layer, forming a pixel defining layer on the protective layer and the base substrate, enclosing the pixel defining layer as a pixel aperture on the protective layer, and etching the protective layer in the pixel aperture to expose the anode layer.

According to one embodiment of the present disclosure, the step of etching the protective layer in the pixel aperture to expose the anode layer comprises a step of removing the protective layer in the pixel aperture using a dry etching or wet etching manner to expose the anode layer.

According to one embodiment of the present disclosure, the step of etching the protective layer in the pixel aperture to expose the anode layer comprises a step of patterning the protective layer in the pixel aperture using a dry etching or wet etching manner to expose the anode layer in a preset shape.

According to one embodiment of the present disclosure, the exposed shape of the anode layer comprises square, round, parallelogram, and pentagram.

According to one embodiment of the present disclosure, the thickness of the protective layer is 1 to 200 nanometers (nm).

According to one embodiment of the present disclosure, a material for the anode layer is a hydrophilic conductive material. A material for the pixel defining layer is a hydrophobic material; a material for the protective layer is a hydrophilic material.

According to one embodiment of the present disclosure, the protective layer is an organic thin film. The organic thin film comprises a hydrophilic photoresist film.

According to one embodiment of the present disclosure, the protective layer is an inorganic thin film. The inorganic thin film comprises a silicon dioxide film or a silicon nitride film.

According to one embodiment of the present disclosure, the anode layer comprises a transparent conductive film.

According to one embodiment of the present disclosure, the material for the pixel defining layer is a photoresist material. The pixel defining layer comprises the pixel defining layer in a single layer, the pixel defining layer in a double layer, and the pixel defining layer in a shape of strip.

According to one embodiment of the present disclosure, after the step of etching the protective layer in the pixel aperture to expose the anode layer, the manufacturing method further comprises a step of forming an organic functional layer in the pixel aperture.

According to one embodiment of the present disclosure, the step of forming the organic functional layer in the pixel aperture comprises a step of: printing an ink material in the pixel aperture, and drying the ink material to form the organic functional layer.

According to one embodiment of the present disclosure, the organic functional layer comprises a hole injection layer, a hole transport layer, a light emitting layer, an electron transport layer, and an electron injection layer.

According to one embodiment of the present disclosure, the ink material comprises a printable solution in response to the organic functional layer.

The present disclosure brings some benefits as follows. A protective layer covers an anode layer before a pixel defining layer is formed in the present disclosure. Therefore, during the formation of a pixel aperture, even if there is some of the residue or other foreign particles into the pixel aperture, the residue or the foreign particles can be removed together with the removal of the protective layer. Therefore, there are no other impurities on the anode layer in the pixel aperture so that an ink material for being printed on the organic functional layer on the anode layer in the pixel aperture can be fully spread out. It prevents the OLED display panel from emitting light unequally and showing any bright or dark spots, which improves the display effect and performance of the OLED display panel and extends the service life of the OLED display panel.

### BRIEF DESCRIPTION OF THE DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which figures those skilled in the art can derive further figures without making any inventive efforts.

FIG. 1 illustrates a flowchart of a conventional method of manufacturing an OLED display panel.

FIG. 2 illustrates a flowchart of a method of manufacturing an OLED display panel according to one embodiment of the present disclosure.

FIG. 3 illustrates a flowchart of a method of manufacturing an OLED display panel according to another embodiment of the present disclosure.

FIG. 4 illustrates a flowchart of a method of manufacturing an OLED display panel according to still another embodiment of the present disclosure.

FIG. 5 illustrates a top view of a pixel aperture of a pixel according to one embodiment of the present disclosure.

FIG. 6 illustrates a top view of a pixel aperture of a pixel according to another embodiment of the present disclosure.

FIG. 7 illustrates a top view of a pixel aperture of a pixel according to still another embodiment of the present disclosure.

### DETAILED DESCRIPTION OF THE EMBODIMENTS

The embodiments of the present disclosure are described in detail hereinafter. Examples of the described embodiments are given in the accompanying drawings, wherein the identical or similar reference numerals constantly denote the identical or similar elements or elements having the identical or similar functions. The specific embodiments described with reference to the attached drawings are all exemplary and are intended to illustrate and interpret the present disclosure, which shall not be construed as causing limitations to the present disclosure.

In the description of the present disclosure, it should be understood that terms such as “center,” “longitudinal,” “lateral,” “length,” “width,” “thickness,” “upper,” “lower,” “front,” “rear,” “left,” “right,” “vertical,” “horizontal,” “top,” “bottom,” “inside,” “outside,” “clockwise,” “counter-clockwise” as well as derivative thereof should be construed to refer to the orientation as then described or as shown in the drawings under discussion. These relative terms are for convenience of description, do not require that the present disclosure be constructed or operated in a particular orientation, and shall not be construed as causing limitations to the present disclosure. In addition, terms such as “first” and “second” are used herein for purposes of description and are not intended to indicate or imply relative importance or significance. Thus, features limited by “first” and “second” are intended to indicate or imply including one or more than one these features. In the description of the present disclosure, “a plurality of” relates to two or more than two, unless otherwise specified.

In the description of the present disclosure, it should be noted that unless there are express rules and limitations, the terms such as “mount,” “connect,” and “bond” should be comprehended in broad sense. For example, it can mean a permanent connection, a detachable connection, or an integrate connection; it can mean a mechanical connection, an electrical connection, or can communicate with each other; it can mean a direct connection, an indirect connection by an intermediate, or an inner communication or an inter-reaction between two elements. A person skilled in the art should understand the specific meanings in the present disclosure according to specific situations.

The disclosure herein provides many different embodiments or examples for realizing different structures of the present disclosure. In order to simplify the disclosure of the present disclosure, components and settings of specific examples are described below. Of course, they are only examples and are not intended to limit the present disclosure. Furthermore, reference numbers and/or letters may be repeated in different examples of the present disclosure. Such repetitions are for simplification and clearness, which per se do not indicate the relations of the discussed embodiments and/or settings. Moreover, the present disclosure provides examples of various specific processes and materials, but the applicability of other processes and/or application of other materials may be appreciated by a person skilled in the art.

The embodiments of the present disclosure are described in detail in conjunction to drawings hereinafter.

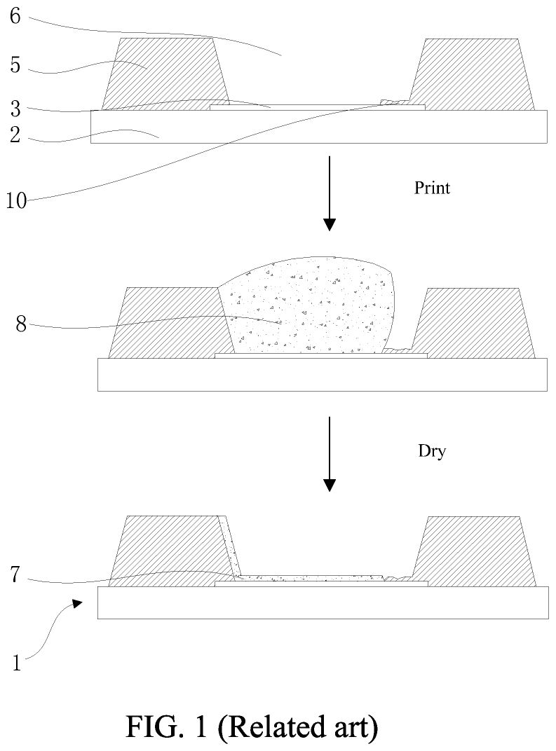

As FIG. 1 illustrates, a pixel defining layer 5 on the anode layer 3 is enclosed to form a pixel aperture 6 while an organic light emitting diode (OLED) display panel 1 is manufactured. The anode layer 3 in the pixel aperture 6 remains some of the residue 10 of the pixel defining layer 5 or other micron-sized foreign particles. As a result, the ink material 8 printed on an organic functional layer 7 on the anode layer 3 in the pixel aperture 6 cannot be spread out completely. Furthermore, the organic functional layer 7 formed after drying is equipped with the edge, and the anode layer 3 where the residue 10 of the pixel defining layer 5 or the foreign particles appear is not covered with the organic functional layer 7. Accordingly, the OLED display panel 1 does not emit light uniformly nor display uniformly without any bright or dark spots.

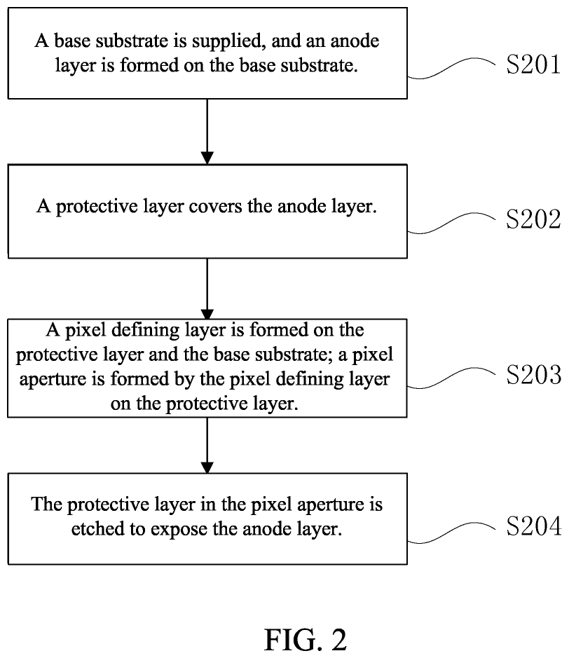

As FIG. 2 illustrates, the embodiment of the present disclosure proposes a method of manufacturing an OLED display panel 1. The manufacturing method includes block S201, block S202, block S203, and block S204.

At block S201, a base substrate is supplied, and an anode layer is formed on the base substrate.

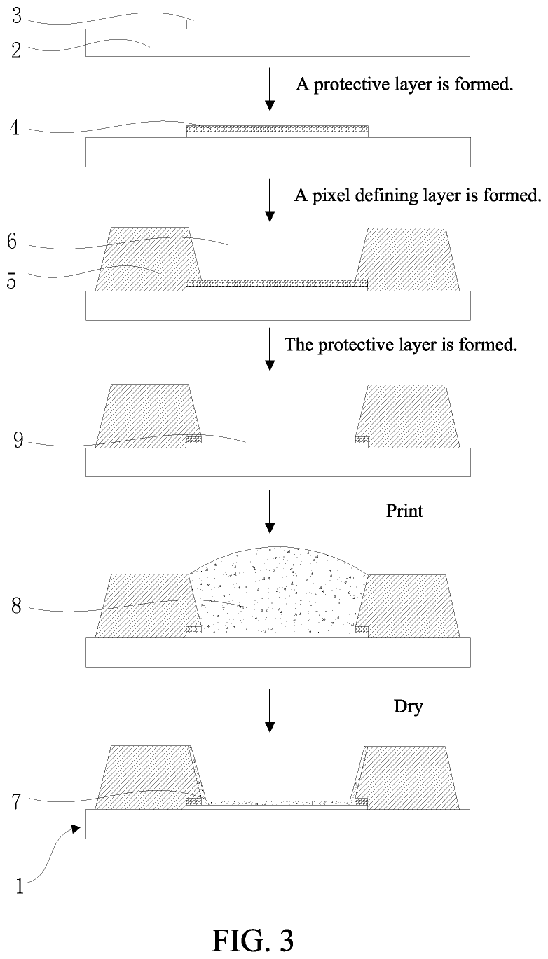

As FIG. 3 illustrates, an anode layer 3 is formed on the base substrate 2. Specifically, the anode layer 3 covers the base substrate 2 completely. Subsequently, the anode layer 3 is patterned to form the plurality of anode layers 3 arranged at intervals.

At block S202, a protective layer covers the anode layer.

As FIG. 3 illustrates, a protective layer 4 covers the anode layer 3. Specifically, the protective layer 4 covers the base substrate 2 and protective layer 4 completely. Subsequently, the protective layer 4 is patterned to let the protective layer 4 to cover the anode layers 3 only.

At block S203, a pixel defining layer is formed on the protective layer and the base substrate; a pixel aperture is formed by the pixel defining layer on the protective layer.

As FIG. 3 illustrates, the pixel defining layer 5 is formed on the protective layer 4 and the base substrate 2. An aperture is formed on the protective layer 4 after the pixel defining layer 5 undergoes the exposure and development technique. The aperture is a pixel aperture 6.

At block S204, the protective layer in the pixel aperture is etched to expose the anode layer.

As FIG. 3 illustrates, the protective layer 4 in the pixel aperture 6 is etched to let the corresponding anode layer 3 to be exposed.

The anode layer 3 includes a transparent conductive film (indium tin oxide, ITO). The pixel defining layer 5 is made of photoresist material. The pixel defining layer 5 includes the pixel defining layer 5 in a single layer, the pixel defining layer 5 in a double layer, the pixel defining layer 5 in a shape of strip, etc. In the present embodiment, a pixel layer in a single layer is taken as an example.

As FIG. 3 illustrates, the protective layer 4 covers the anode layer 3 before the pixel defining layer 5 is formed in the present disclosure. Therefore, during the formation of the pixel aperture 6, even if there is some of the residue or other foreign particles into the pixel aperture 6, the residue or the foreign particles may be removed together with the removal of the protective layer 4. Therefore, there is no other impurities on the anode layer 3 in the pixel aperture 6 so that the ink material 8 for being printed on the organic functional layer 7 on the anode layer 3 in the pixel aperture 6 can be fully spread out. It ensures that the OLED display panel 1 emits light uniformly without any bright or dark spots, which improves the display effect and performance of the OLED display panel 1 and extends the service life of the OLED display panel 1.

The block of etching the protective layer 4 in the pixel aperture to expose the anode layer 3 includes a step as follows.

The protective layer 4 in the pixel aperture 6 is removed using a dry etching or wet etching manner to expose the anode layer 3.

In the present embodiment, depending on the material of the protective layer 4, either dry etching or wet etching is adopted to remove the protective layer 4 in the pixel aperture 6 and expose a part of the anode layer 3. The exposure of the anode layer 3 becomes a light emitting area 9. Of course, the protective layer 4 can also be removed by exposure based on the type of material.

In another embodiment, the thickness of a protective layer 4 is 1 to 200 nanometers (nm). It prevents the material for a pixel defining layer 5 from being exposed to the surface of an anode layer 3. Besides, it is not too thick for the protective layer 4 to be etched and removed while the etching time is too long to affect the surface of the pixel defining layer 5.

In another embodiment, material for an anode layer 3 is a hydrophilic conductive material. Material for a pixel defining layer 5 is a hydrophobic material. Material for a protective layer 4 is a hydrophilic material.

In the present embodiment, the printable ink material 8 is a liquid, containing a large amount of water. Only the anode layer 3 is a hydrophilic material can the ink material 8 which is printed on the surface of the anode layer 3 be fully spread out. Furthermore, in order to limit the printable ink in a single pixel aperture 6 without touching the ink material 8 in the pixel aperture 6 adjacent the single pixel aperture 6, the material of the pixel defining layer 5 is a hydrophobic material. The protective layer 4 is made of hydrophilic material so that the residual protective layer 4 does not influence the printing of the ink material 8. Even if there is some of the residue, it does not affect the spreading of the ink material 8 on the anode layer 3.

In another embodiment, a protective layer 4 includes an organic thin film or an inorganic thin film. The selectable material for the protective layer 4 is of a wide range so the cost of material is controllable.

The organic film includes a hydrophilic photoresist material. The inorganic film includes a silicon dioxide film or a silicon nitride film.

In another embodiment, as FIG. 3 illustrates, a step of etching a protective layer 4 in a pixel aperture 6 to expose an anode layer 3 further includes a step subsequently.

An organic functional layer 7 is formed in the pixel aperture 6.

The organic functional layer 7 includes a hole injection layer, a hole transport layer, a light emitting layer, an electron transport layer, an electron injection layer, etc.

In another embodiment, a step of forming an organic functional layer 7 in a pixel aperture 6 includes a step as follows.

An ink material 8 is printed in a pixel aperture 6.

The ink material 8 is dried to form the organic functional layer 7.

The ink material 8 includes a printable solution in response to the organic functional layer 7. The organic functional layer 7 is a film that is formed after the ink material layer 8 undergoes a drying process.

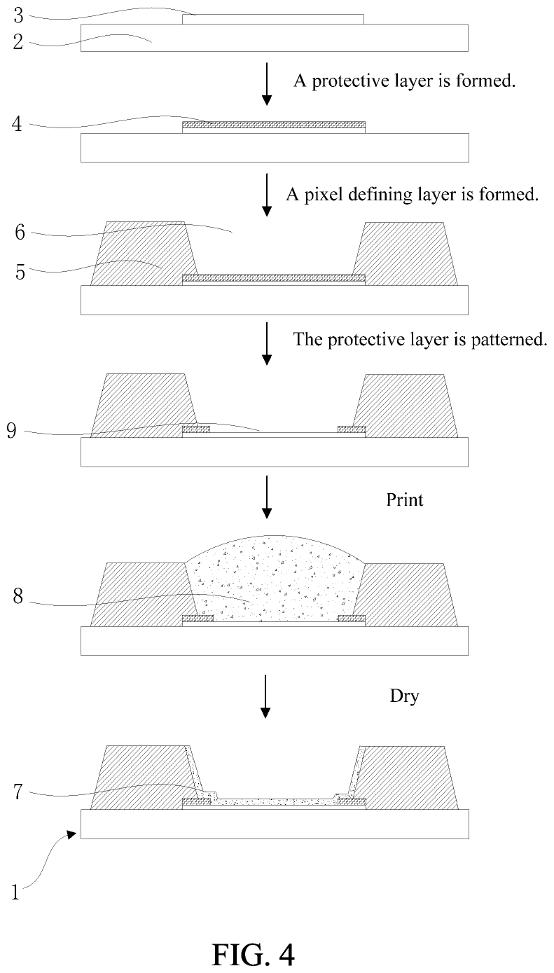

As FIG. 4 illustrates, the present disclosure further proposes a method of manufacturing an organic light emitting diode (OLED) display panel 1. Different from the above-described embodiment, a protective layer 4 in a pixel aperture 6 is etched to expose an anode layer. The manufacturing method includes a step as follows.

The protective layer 4 in the pixel aperture 6 is patterned using a dry etching or wet etching manner to expose the anode layer 3 in a preset shape.

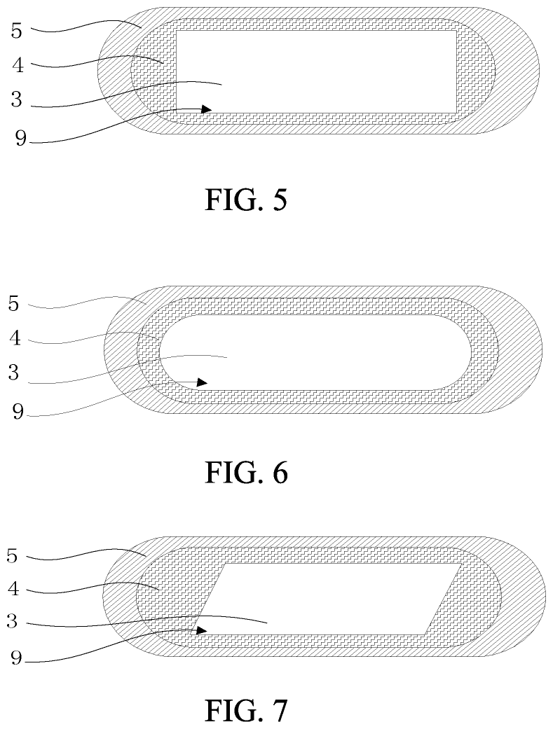

As illustrated in FIG. 5 to FIG. 7, the exposed shape of the anode layer 3 includes square, round (or oval), parallelogram, and pentagram.

The aim of patterning the protective layer 4 in the pixel aperture 6 is to avoid the exposed anode layer 3 from remaining the pixel defining layer 5, which is hydrophobic, to improve the display effect of the OLED display panel 1. On the other hand, the protective layer 4 is patterned to make the expose anode layer 3 show various preset shapes. As illustrated in FIG. 5 to FIG. 7, of course, the preset shape of the expose anode layer 3 is not limited to the patterns listed in FIG. 5 to FIG. 7. The preset shape of the expose anode layer 3 may be other specific patterns to obtain the light emitting area 9 in various shapes, which can improve the viewing angle of the OLED display panel 1. In addition, compared with the exposure and development technique by which the pixel defining layer 5 is patterned to form the light emitting area 9 in various shapes, no masks are needed for the dry etching or wet etching by which the protective layer 4 is patterned. Therefore, the production cost is less using the dry etching or wet etching.

The present disclosure has been described with a preferred embodiment thereof. The preferred embodiment is not intended to limit the present disclosure, and it is understood that many changes and modifications to the described embodiment can be carried out without departing from the scope and the spirit of the disclosure that is intended to be limited only by the appended claims.

1. A manufacturing method of an organic light emitting diode (OLED) display panel, comprising steps of:
supplying a base substrate;
forming an anode layer on the base substrate;
covering a protective layer on the anode layer;
forming a pixel defining layer on the protective layer and the base substrate;
enclosing the pixel defining layer as a pixel aperture on the protective layer; and
etching the protective layer in the pixel aperture to expose the anode layer;
wherein the protective layer is an organic thin film.

2. The manufacturing method of claim 1, wherein the step of etching the protective layer in the pixel aperture to expose the anode layer comprises a step of:
removing the protective layer in the pixel aperture using a dry etching or wet etching manner to expose the anode layer.

3. The manufacturing method of claim 1, wherein the step of etching the protective layer in the pixel aperture to expose the anode layer comprises a step of:
patterning the protective layer in the pixel aperture using a dry etching or wet etching manner to expose the anode layer in a preset shape.

4. The manufacturing method of claim 3, wherein the exposed shape of the anode layer comprises square, round, parallelogram, and pentagram.

5. The manufacturing method of claim 1, wherein the thickness of the protective layer is 1 to 200 nanometers (nm).

6. The manufacturing method of claim 1, wherein a material for the anode layer is a hydrophilic conductive material, a material for the pixel defining layer is a hydrophobic material, a material for the protective layer is a hydrophilic material.

7. The manufacturing method of claim 6, wherein the organic thin film comprises a hydrophilic photoresist film.

8. The manufacturing method of claim 6, wherein the protective layer is an inorganic thin film, the inorganic thin film comprises a silicon dioxide film or a silicon nitride film.

9. The manufacturing method of claim 6, wherein the anode layer comprises a transparent conductive film.

10. The manufacturing method of claim 6, wherein the material for the pixel defining layer is a photoresist material, the pixel defining layer comprises the pixel defining layer in a single layer, the pixel defining layer in a double layer, and the pixel defining layer in a shape of strip.

11. The manufacturing method of claim 1, wherein after the step of etching the protective layer in the pixel aperture to expose the anode layer, the manufacturing method further comprises a step of:
forming an organic functional layer in the pixel aperture.

12. The manufacturing method of claim 11, wherein the step of forming the organic functional layer in the pixel aperture comprises a step of:
printing an ink material in the pixel aperture; and
drying the ink material to form the organic functional layer.

13. The manufacturing method of claim 12, wherein the organic functional layer comprises a hole injection layer, a hole transport layer, a light emitting layer, an electron transport layer, and an electron injection layer.

14. The manufacturing method of claim 13, wherein the ink material comprises a printable solution in response to the organic functional layer.
